(19) United States
(12) Patent Application Publication
(10) Pub. No.: US 2025/0151516 A1
(43) Pub. Date: May 8, 2025

(54) DISPLAY DEVICE PRODUCTION METHOD AND DISPLAY DEVICE

(71) Applicant: Sharp Display Technology Corporation, Kameyama City, Mie (JP)

(72) Inventors: YASUSHI ASAOKA, Sakai City, Osaka (JP); Sentaro KIDA, Sakai City, Osaka (JP); Takahiro ADACHI, Sakai City, Osaka (JP)

(21) Appl. No.: 18/837,680

(22) PCT Filed: Apr. 20, 2022
(86) PCT No.: PCT/JP2022/018302

§ 371 Date: Aug. 12, 2024

(51) Int. Cl. H10K 59/12; H10K 59/122; H10K 59/35; H10K 71/12

(52) U.S. Cl. CPC H10K 59/1201; H10K 59/122; H10K 59/35; H10K 71/12

(57) ABSTRACT

A display device includes a first light-emitting layer formed continuously over a plurality of first pixels, and a second light-emitting layer formed continuously over a plurality of second pixels and not overlapping the first light-emitting layer in a plan view. The second light-emitting layer includes a solution drop material, and the first light-emitting layer is formed overlapping a part of an outer peripheral portion of each pixel in a plan view.

### TECHNICAL FIELD

The disclosure relates to a display device manufacturing method and a display device.

### BACKGROUND ART

In an ultra-high definition element, in order to separately pattern light-emitting layers for each pixel, a technique is known in which regarding light-emitting layers of a plurality of colors of RGB continuously formed over a plurality of pixels, light-emitting layers of the second and third colors are separately painted using a capillary phenomenon (PTL 1).

### CITATION LIST

### Patent Literature

PTL 1: JP 2010-192215 A

### SUMMARY

### Technical Problem

However, in the technique disclosed in PTL 1 above, it is necessary to provide a high partition in order to cause a capillary phenomenon for separately patterning the light-emitting layers of the second and third colors. The high partition of PTL 1 remains even after the light-emitting layers are separately patterned. Therefore, when a common electrode is applied on these light-emitting layers, there is a possibility that the common electrode is interrupted at an inclined surface caused by the partition.

According to an aspect of the disclosure, an object is to provide a display device manufacturing method and a display device capable of separately patterning light-emitting layers by using a capillary phenomenon without leaving a high partition.

### Solution to Problem

In order to solve the problem above, according to an aspect of the disclosure, there is provided a display device manufacturing method including:
forming a first light layer in a planar shape including a first light material associated with first light having a first wavelength;
forming a mask pattern on the first light layer, the mask pattern including an opening formed over a plurality of sub-pixel formation regions;
removing a portion of the first light layer located below the opening;
feeding an ink to below at least a portion of the opening, the ink including a second light material associated with second light having a second wavelength to form a second light layer including the second light material; and
removing the mask pattern.

In order to solve the problem above, according to an aspect of the disclosure, there is provided a display device including:
a first light layer continuously formed over a plurality of first pixels in association with first light having a first wavelength; and
a second light layer continuously formed over a plurality of second pixels in association with second light having a second wavelength, the second light layer not overlapping the first light layer in a plan view,
wherein the second light layer includes a solid dispersed or dissolved in a solution drop material in a liquid state, and
the first light layer is formed overlapping a part of an outer peripheral portion of each of the pixels in a plan view.

### Advantageous Effects of Disclosure

According to an aspect of the disclosure, it is possible to separately pattern light-emitting layers by using a capillary phenomenon without remaining a high partition.

### BRIEF DESCRIPTION OF DRAWINGS

FIG. 1 is a plan view of a display device according to a first embodiment.

FIG. 2 is a cross-sectional view illustrating a manufacturing method for the display device.

FIG. 3 is a plan view corresponding to FIG. 2.

FIG. 4 is another cross-sectional view illustrating the manufacturing method for the display device.

FIG. 5 is a plan view corresponding to FIG. 4.

FIG. 6 is still another cross-sectional view illustrating the manufacturing method for the display device.

FIG. 7 is a plan view corresponding to FIG. 6.

FIG. 8 is still another cross-sectional view illustrating the manufacturing method for the display device.

FIG. 9 is a plan view corresponding to FIG. 8.

FIG. 10 is a cross-sectional view illustrating a manufacturing method for a display device according to a second embodiment.

FIG. 11 is another cross-sectional view illustrating the manufacturing method for the display device.

FIG. 12 is still another cross-sectional view illustrating the manufacturing method for the display device.

FIG. 13 is still another cross-sectional view illustrating the manufacturing method for the display device.

FIG. 14 is still another cross-sectional view illustrating the manufacturing method for the display device.

FIG. 15 is still another cross-sectional view illustrating the manufacturing method for the display device.

FIG. 16 is still another cross-sectional view illustrating the manufacturing method for the display device.

FIG. 17 is still another cross-sectional view illustrating the manufacturing method for the display device.

FIG. 18 is a cross-sectional view illustrating a manufacturing method for a display device according to a third embodiment.

FIG. 19 is another cross-sectional view illustrating the manufacturing method for the display device.

FIG. 20 is still another cross-sectional view illustrating the manufacturing method for the display device.

FIG. 21 is still another cross-sectional view illustrating the manufacturing method for the display device.

FIG. 22 is still another cross-sectional view illustrating the manufacturing method for the display device.

FIG. 23 is still another cross-sectional view illustrating the manufacturing method for the display device.

FIG. 24 is still another cross-sectional view illustrating the manufacturing method for the display device.

FIG. 25 is still another cross-sectional view illustrating the manufacturing method for the display device.

FIG. 26 is a cross-sectional view illustrating a manufacturing method for a display device according to a fourth embodiment.

FIG. 27 is a plan view corresponding to FIG. 26.

FIG. 28 is another cross-sectional view illustrating the manufacturing method for the display device.

FIG. 29 is a plan view corresponding to FIG. 28.

FIG. 30 is still another cross-sectional view illustrating the manufacturing method for the display device.

FIG. 31 is a plan view corresponding to FIG. 30.

FIG. 32 is still another cross-sectional view illustrating the manufacturing method for the display device.

FIG. 33 is a plan view corresponding to FIG. 32.

FIG. 34 is still another cross-sectional view illustrating the manufacturing method for the display device.

FIG. 35 is a plan view corresponding to FIG. 34.

FIG. 36 is a plan view of a display device according to a fifth embodiment.

FIG. 37 is a plan view of a display device according to a sixth embodiment.

FIG. 38 is a cross-sectional view corresponding to FIG. 37.

FIG. 39 is a plan view of a display device according to a modified example of the sixth embodiment.

FIG. 40 is a cross-sectional view corresponding to FIG. 39.

FIG. 41 is a cross-sectional view illustrating a manufacturing method for a display device according to a seventh embodiment.

FIG. 42 is a plan view corresponding to FIG. 41.

FIG. 43 is another cross-sectional view illustrating the manufacturing method for the display device.

FIG. 44 is a plan view corresponding to FIG. 43.

FIG. 45 is still another cross-sectional view illustrating the manufacturing method for the display device.

FIG. 46 is a plan view corresponding to FIG. 45.

FIG. 47 is still another cross-sectional view illustrating the manufacturing method for the display device.

FIG. 48 is a plan view corresponding to FIG. 47.

FIG. 49 is a cross-sectional view of the display device.

### DESCRIPTION OF EMBODIMENTS

### First Embodiment

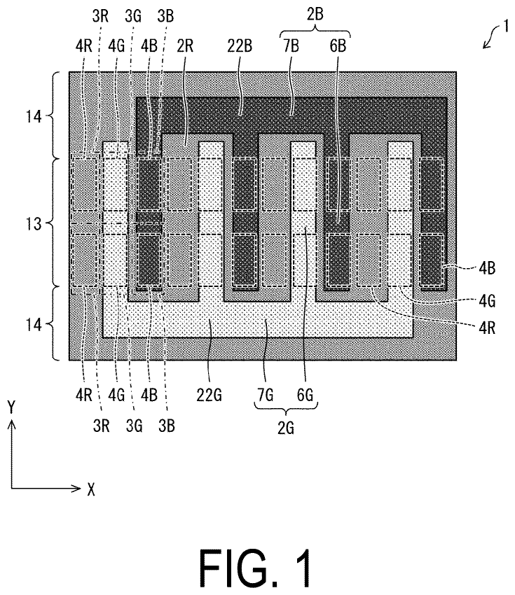

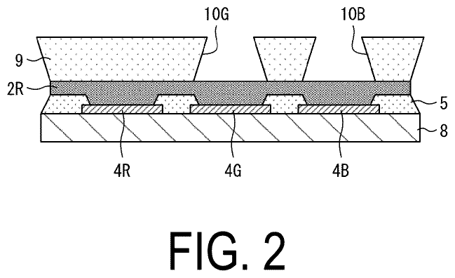

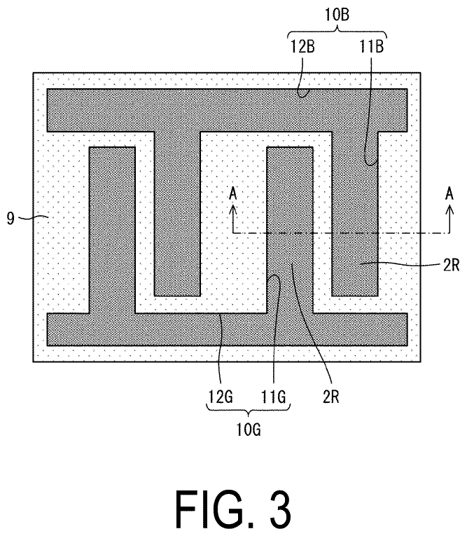

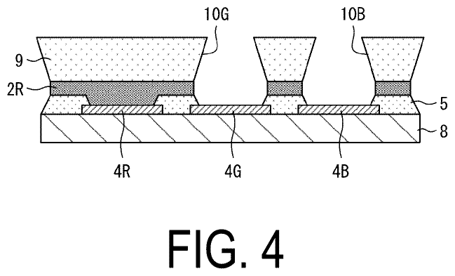

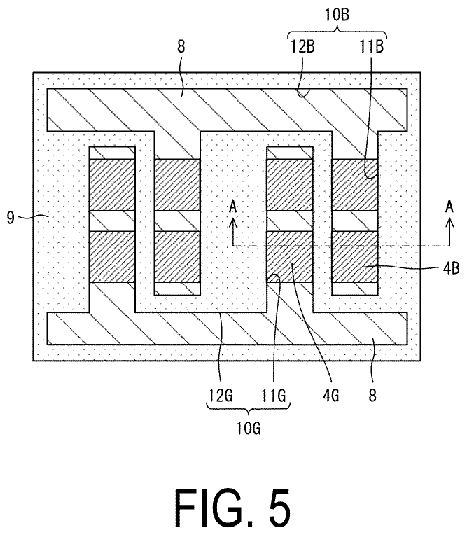

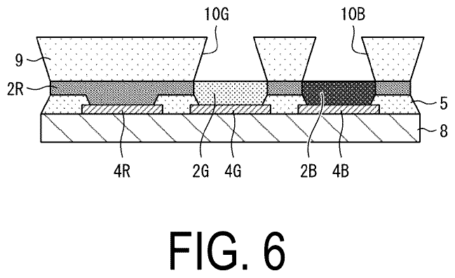

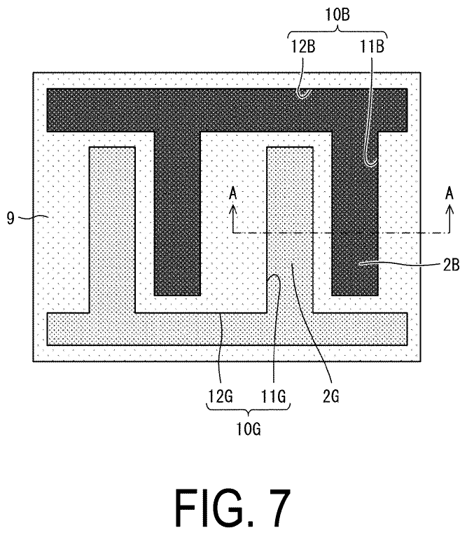

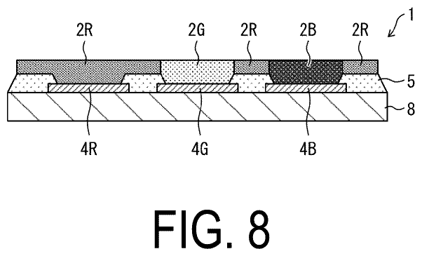

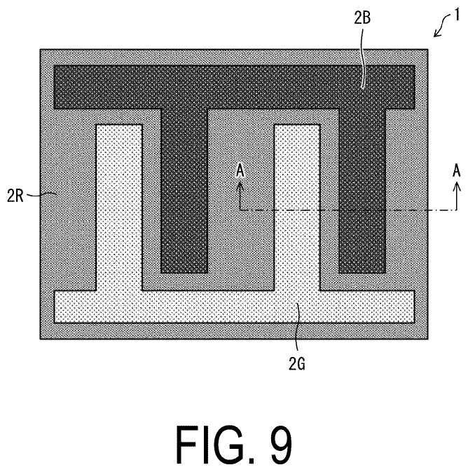

FIG. 1 is a plan view of a display device 1 according to a first embodiment. FIG. 2 is a cross-sectional view illustrating a manufacturing method for the display device 1. FIG. 3 is a plan view corresponding to FIG. 2. FIG. 4 is another cross-sectional view illustrating the manufacturing method for the display device 1. FIG. 5 is a plan view corresponding to FIG. 4. FIG. 6 is still another cross-sectional view illustrating the manufacturing method for the display device 1. FIG. 7 is a plan view corresponding to FIG. 6. FIG. 8 is still another cross-sectional view illustrating the manufacturing method for the display device 1. FIG. 9 is a plan view corresponding to FIG. 8.

FIG. 2 is a cross-sectional view taken along arrow A-A in FIG. 3. FIG. 4 is a cross-sectional view taken along arrow A-A in FIG. 5. FIG. 6 is a cross-sectional view taken along arrow A-A in FIG. 7. FIG. 8 is a cross-sectional view taken along arrow A-A in FIG. 9.

The display device 1 includes a first light-emitting layer 2R (first light layer) formed continuously over a plurality of first pixels 3R formed adjacent to each other along a Y direction, and a second light-emitting layer 2G (second light layer) formed continuously over a plurality of second pixels 3G formed adjacent to each other along the Y direction and not overlapping the first light-emitting layer 2R in a plan view. The second light-emitting layer 2G includes a solid dispersed or dissolved in a solution drop material 22G in a liquid state at the time of dropping. The first light-emitting layer 2R is formed to overlap a part of the outer peripheral portion of each pixel in a plan view.

Each of the first pixels 3R includes a first pixel electrode 4R corresponding to the first light-emitting layer 2R. Each of the second pixels 3G includes a second pixel electrode 4G corresponding to the second light-emitting layer 2G. An intermediate line between the first pixel electrodes 4R adjacent to each other along the Y direction is a boundary line between the adjacent first pixels 3R. An intermediate line between the second pixel electrodes 4G adjacent to each other along the Y direction is a boundary line between the adjacent second pixels 3G. An intermediate line between the first pixel electrode 4R and the second pixel electrode 4G adjacent to each other along a X direction is a boundary line between the first pixel 3R and the second pixel 3G adjacent to each other.

For example, as illustrated in FIG. 8, the display device 1 further includes an edge cover 5 covering edges of the first pixel electrode 4R and the second pixel electrode 4G. The first light-emitting layer 2R is formed to overlap a part of the edge cover 5 in a plan view.

For example, as illustrated in FIG. 8, the second light-emitting layer 2G is formed such that an end face of the second light-emitting layer 2G is in contact with an end face of a part of the first light-emitting layer 2R. The second light-emitting layer 2G includes a plurality of pixel regions 6G formed by the plurality of second pixels 3G adjacent to each other, and a connection region 7G connecting the plurality of pixel regions 6G. The second light-emitting layer 2G includes quantum dots.

For example, as illustrated in FIG. 8, the first light-emitting layer 2R is formed to overlap a part of the edge cover 5 in a plan view, and the second light-emitting layer 2G is formed to overlap the remaining part of the edge cover 5 in a plan view.

The display device 1 further includes a third light-emitting layer 2B continuously formed over a plurality of third pixels 3B formed adjacent to each other along the Y direction and not overlapping the first light-emitting layer 2R and the second light-emitting layer 2G in a plan view. The third light-emitting layer 2B includes a solid dispersed or dissolved in a solution drop material 22B in a liquid state at the time of dropping. For example, as illustrated in FIG. 8, the third light-emitting layer 2B is formed such that an end face of the third light-emitting layer 2B is in contact with an end face of a part of the first light-emitting layer 2R.

The first pixel 3R is disposed between the second pixel 3G and the third pixel 3B.

The display device 1 includes a display region 13 and a non-display region 14 disposed around the display region 13. The first pixel 3R, the second pixel 3G, and the third pixel 3B are disposed in the display region 13. The first light-emitting layer 2R, the second light-emitting layer 2G, and the third light-emitting layer 2B are formed over the display region 13 and the non-display region 14. The pixel region 6G of the second light-emitting layer 2G is formed in the display region 13, and the connection region 7G of the second light-emitting layer 2G is formed in the non-display region 14. A pixel region 6B of the third light-emitting layer 2B is formed in the display region 13, and a connection region 7B of the third light-emitting layer 2B is formed in the non-display region 14.

Next, a manufacturing method of the display device 1 configured in this way will be described.

First, as illustrated in FIG. 2, a substrate 8 is formed with the first pixel electrode 4R for causing a first light-emitting material included in the first light-emitting layer 2R to emit light, the second pixel electrode 4G for causing a second light-emitting material included in the second light-emitting layer 2G to emit light, and a third pixel electrode 4B for causing a third light-emitting material included in the third light-emitting layer 2B to emit light. The edge cover 5 disposed between the first pixel electrode 4R, the second pixel electrode 4G, and the third pixel electrode 4B is formed on the substrate 8.

Thereafter, the planar first light-emitting layer 2R (first light layer) including the first light-emitting material (first light material) associated with first light having a first wavelength is formed on the entire surface of the substrate 8 to cover the first pixel electrode 4R, the second pixel electrode 4G, the third pixel electrode 4B, and the edge cover 5 (step of forming first light layer). The first light-emitting material is a material constituting the first light-emitting layer 2R emitting the first light having the first wavelength.

As illustrated in FIGS. 2 and 3, a mask pattern 9 including openings 10G and 10B formed to extend over a plurality of sub-pixel formation regions is formed on the first light-emitting layer 2R (step of forming mask pattern on first light layer). As illustrated in FIG. 3, the opening 10G includes a capillary pattern portion 11G corresponding to the pixel region 6G of the second light-emitting layer 2G and a drop pattern portion 12G (connection pattern portion) corresponding to the connection region 7G of the second light-emitting layer 2G. The opening 10B includes a capillary pattern portion 11B corresponding to the pixel region 6B of the third light-emitting layer 2B and a drop pattern portion 12B (connection pattern portion) corresponding to the connection region 7B of the third light-emitting layer 2B. The mask pattern 9 is formed by forming a photoresist film on the first light-emitting layer 2R and then processing the photoresist film by photolithography to form the openings 10G and 10B. The opening 10G and the opening 10B are separated from each other by the photoresist film of the mask pattern 9.

The mask pattern 9 is formed to overlap the edge cover 5 in a plan view.

Next, as illustrated in FIGS. 4 and 5, portions of the first light-emitting layer 2R located below the openings 10G and 10B in the first light-emitting layer 2R are removed (step of removing first light-emitting layer). For example, the first light-emitting layer 2R is etched with TMAH (tetramethylammonium hydroxide aqueous solution), acid, or the like.

Thereafter, as illustrated in FIGS. 6 and 7, ink including the second light-emitting material (second light material) associated with second light having a second wavelength is fed below at least a portion of the opening 10G to form the second light-emitting layer 2G (second light layer) including the second light-emitting material (step of forming second light layer). Ink is fed by using a capillary phenomenon in the opening 10G. The second light-emitting material is a material constituting the second light-emitting layer 2G emitting the second light having the second wavelength.

Ink including the second light-emitting material is fed below the opening 10G, and ink including the third light-emitting material (third light material) is fed below the opening 10B to form the third light-emitting layer 2B (third light layer) including the third light-emitting material (step of forming third light layer). Since the opening 10G and the opening 10B are separated from each other by the photoresist film of the mask pattern 9, mixing of the ink including the second light-emitting material and the ink including the third light-emitting material can be suppressed.

The third light-emitting layer 2B may be formed simultaneously with the second light-emitting layer 2G, or may be formed before or after the second light-emitting layer 2G in terms of time.

The display device 1 includes a plurality of first pixels 3R, second pixels 3G, and third pixels 3B. The second light-emitting layer 2G corresponding to the second light-emitting material is formed through the plurality of second pixels 3G. The third light-emitting layer 2B corresponding to the third light-emitting material is formed through the plurality of third pixels 3B.

The ink including the second light-emitting material is dropped on the drop pattern portion 12G of the opening 10G. The ink including the third light-emitting material is dropped on the drop pattern portion 12B of the opening 10B.

The second light-emitting layer 2G is formed so that the end face of the first light-emitting layer 2R is in contact with the end face of the second light-emitting layer 2G. The third light-emitting layer 2B is formed so that the end face of the first light-emitting layer 2R is in contact with the end face of the third light-emitting layer 2B.

The ink dropped on the drop pattern portion 12G of the opening 10G spreads from the drop pattern portion 12G toward the capillary pattern portion 11G of the opening 10G by a capillary phenomenon. The ink dropped on the drop pattern portion 12B of the opening 10B spreads from the drop pattern portion 12B toward the capillary pattern portion 11B of the opening 10B by a capillary phenomenon.

When the mask pattern 9 is removed from on the first light-emitting layer 2R, the plurality of light-emitting layers that are separately patterned (first light-emitting layer 2R, second light-emitting layer 2G, and third light-emitting layer 2B) of the display device 1 are completed as illustrated in FIG. 8 (step of removing mask pattern). Thus, three colors of the first light-emitting layer 2R, the second light-emitting layer 2G, and the third light-emitting layer 2B can be separately patterned by one patterning based on the mask pattern 9. Furthermore, if necessary, a charge transport layer and a common electrode are further formed to cover the separately patterned plurality of light-emitting layers, thereby completing the display device 1. Thus, three colors of the first light-emitting layer 2R, the second light-emitting layer 2G, and the third light-emitting layer 2B can be separately patterned by performing patterning twice. The first light-emitting layer 2R, the second light-emitting layer 2G, and the third light-emitting layer 2B emit EL light by injecting charges from the pixel electrode and the common electrode. A desired light-emitting layer without mixed-color EL light emission can be formed in each pixel.

The first light-emitting layer 2R is continuously formed through the plurality of first pixels 3R. The second light-emitting layer 2G is continuously formed through the plurality of second pixels 3G. The third light-emitting layer 2B is continuously formed through the plurality of third pixels 3B. Thus, chipping of pixels due to pattern edges of the first light-emitting layer 2R, the second light-emitting layer 2G, and the third light-emitting layer 2B is less likely to occur. Since the photolithography is performed only once for separate-patterning, overlapping of the light-emitting layers due to pattern deviation does not occur. Since the first light-emitting layer 2R is also formed on the edge cover 5 and the gaps between the light-emitting layers are small, the occurrence of leakage current on the edge cover 5 is suppressed.

### Second Embodiment

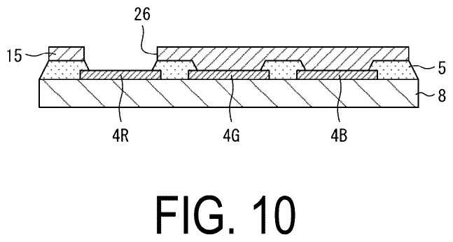

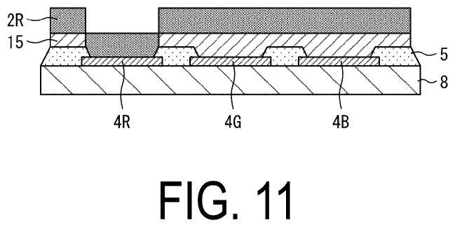

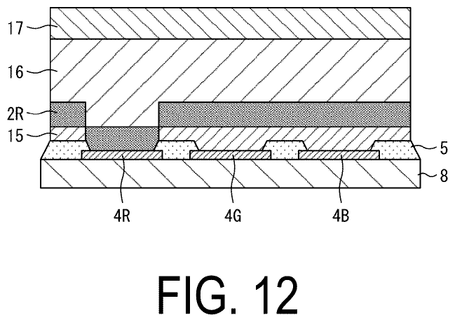

FIG. 10 is a cross-sectional view illustrating a manufacturing method for a display device 1A according to a second embodiment. FIG. 11 is another cross-sectional view illustrating the manufacturing method for the display device 1A. FIGS. 12 to 17 are still another cross-sectional views illustrating the manufacturing method for the display device 1A. FIGS. 10 to 17 are cross-sectional views taken along arrow A-A similarly to FIGS. 2, 4, 6, and 8, for example. Constituent elements similar to/same as the constituent elements described above are given the same reference numerals. Thus, detailed descriptions of the constituent elements are not repeated.

Hereinafter, the manufacturing method for the display device 1A will be described.

First, as illustrated in FIG. 10, the first pixel electrode 4R, the second pixel electrode 4G, and the third pixel electrode 4B are formed on the substrate 8. The edge cover 5 disposed between the first pixel electrode 4R, the second pixel electrode 4G, and the third pixel electrode 4B is formed on the substrate 8.

A first light-emitting layer mask pattern 15 having a first light-emitting layer formation opening 26 for forming the first light-emitting layer 2R is formed on the substrate 8 by photolithography such that the first pixel electrode 4R is exposed to cover the second pixel electrode 4G and the third pixel electrode 4B. Note that, although the edge cover 5 may or may not be covered with the first light-emitting layer mask pattern 15, FIGS. 10 to 17 illustrates an example in which the edge cover 5 is covered with the first light-emitting layer mask pattern 15. The first light-emitting layer formation opening 26 may be an opening pattern formed to correspond to one of the first pixel electrodes 4R included in each pixel, or may be a plurality of belt-shaped opening patterns formed to correspond to a plurality of the first pixel electrodes 4R included in each pixel column.

Next, as illustrated in FIG. 11, the first light-emitting material is applied to the entire surface of the substrate 8 to cover the first light-emitting layer mask pattern 15 and the first light-emitting layer formation opening 26, thereby forming the first light-emitting layer 2R.

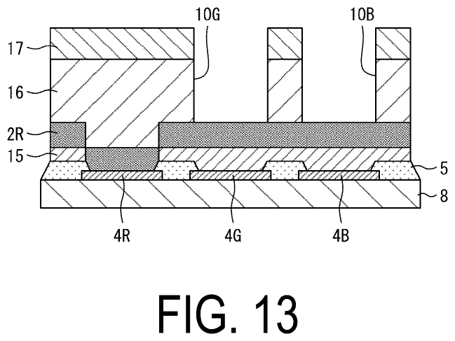

Thereafter, as illustrated in FIG. 12, a protection layer 16 and a photoresist 17 are formed on the first light-emitting layer 2R. As illustrated in FIG. 13, the protection layer 16 and the photoresist 17 are subjected to patterning to correspond to the second pixel electrode 4G and the third pixel electrode 4B to form the openings 10G and 10B.

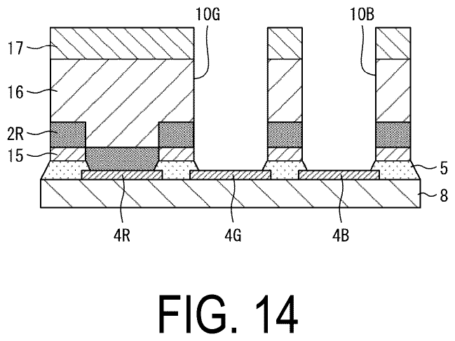

Next, as illustrated in FIG. 14, the first light-emitting layer 2R and the first light-emitting layer mask pattern 15 existing in the openings 10G and 10B of the protection layer 16 and the photoresist 17 are removed. By first removing the first light-emitting layer mask pattern 15 below the first light-emitting layer 2R, the residue of the first light-emitting layer 2R is less likely to remain, and color mixing due to EL (Electro-Luminescence) light emission from the residue of the first light-emitting layer 2R can be suppressed.

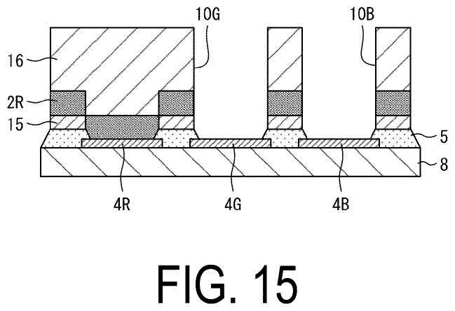

Then, as illustrated in FIG. 15, the photoresist 17 is removed. When the photoresist 17 damages the second light-emitting layer 2G and the third light-emitting layer 2B, by removing only the photoresist 17 in advance, it is possible to suppress contact between the second light-emitting layer 2G and the third light-emitting layer 2B and the photoresist 17 which is dissolved in the peeling solution in the step of peeling the protection layer 16. When the photoresist 17 does not damage the second light-emitting layer 2G and the third light-emitting layer 2B, the prior removal of the photoresist 17 is unnecessary.

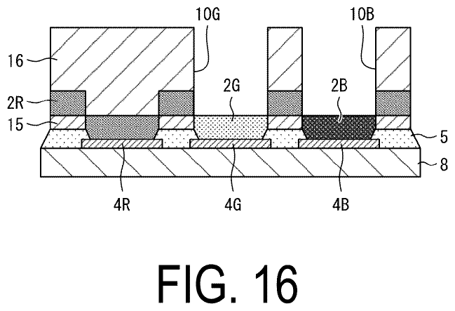

As illustrated in FIG. 16, the ink dropped on the drop pattern portion 12G of the opening 10G spreads from the drop pattern portion 12G toward the capillary pattern portion 11G of the opening 10G by a capillary phenomenon to form the second light-emitting layer 2G. The ink dropped on the drop pattern portion 12B of the opening 10B spreads from the drop pattern portion 12B toward the capillary pattern portion 11B of the opening 10B by a capillary phenomenon to form the third light-emitting layer 2B.

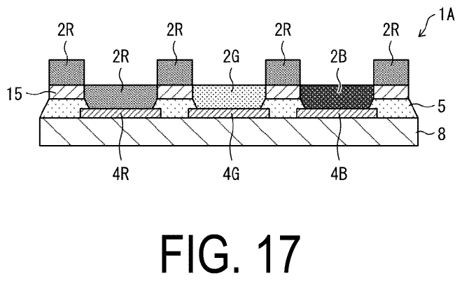

Next, as illustrated in FIG. 17, a plurality of light-emitting layers can be separately patterned by removing the protection layer 16, and further, if necessary, the charge transport layer and the common electrode are formed to cover the separately patterned light-emitting layers, thereby completing the display device 1A. Thus, three colors of the first light-emitting layer 2R, the second light-emitting layer 2G, and the third light-emitting layer 2B can be separately patterned by performing patterning twice. A desired light-emitting layer without mixed-color EL light emission can be formed in each pixel.

Since the first light-emitting layer mask pattern 15 and the first light-emitting layer 2R are layered on the edge cover 5 and the gaps between the light-emitting layers are small, the occurrence of leakage current on the edge cover 5 is suppressed.

### Third Embodiment

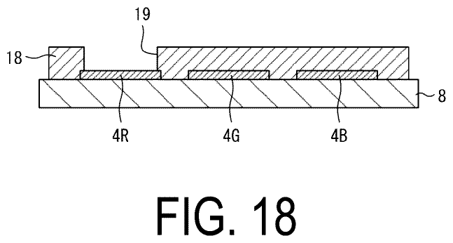

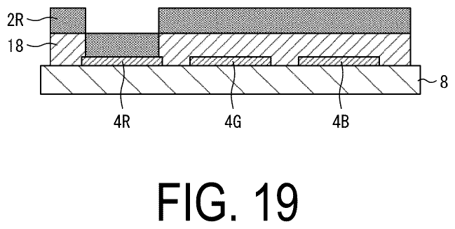

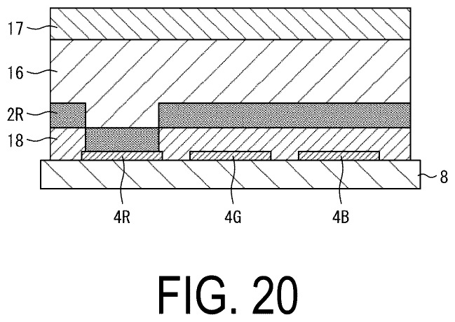

FIG. 18 is a cross-sectional view illustrating a manufacturing method for a display device 1B according to a third embodiment. FIG. 19 is another cross-sectional view illustrating the manufacturing method for the display device 1B. FIGS. 20 to 25 are still another cross-sectional views illustrating the manufacturing method for the display device 1B. FIGS. 19 to 25 are cross-sectional views taken along arrow A-A similarly to FIGS. 2, 4, 6, and 8, for example. Constituent elements similar to/same as the constituent elements described above are given the same reference numerals. Thus, detailed descriptions of the constituent elements are not repeated.

Hereinafter, the manufacturing method for the display device 1B will be described.

First, as illustrated in FIG. 18, the first pixel electrode 4R, the second pixel electrode 4G, and the third pixel electrode 4B are formed on the substrate 8. An edge cover is not formed.

A photoresist 18 including an opening 19 for forming the first light-emitting layer 2R is formed on the substrate 8 by photolithography such that the first pixel electrode 4R is exposed to cover the second pixel electrode 4G and the third pixel electrode 4B. The opening 19 may be a plurality of opening patterns in which each pixel is isolated, or may be a plurality of belt-shaped opening patterns in which each pixel row is continuous. The opening 19 may be formed in the photoresist 18 to overlap parts of the end portions of the first pixel electrode 4R.

Next, as illustrated in FIG. 19, the first light-emitting material is applied to the entire surface of the substrate 8 to cover the photoresist 18 and the opening 19, thereby forming the first light-emitting layer 2R.

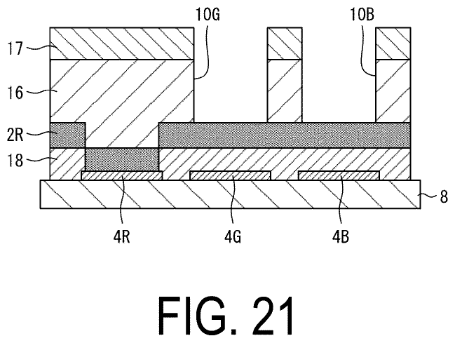

Thereafter, as illustrated in FIG. 20, the protection layer 16 and the photoresist 17 are formed on the first light-emitting layer 2R. As illustrated in FIG. 21, the protection layer 16 and the photoresist 17 are subjected to patterning to correspond to the second pixel electrode 4G and the third pixel electrode 4B to form the openings 10G and 10B. The openings 10G and 10B may be formed such that the protection layer 16 and the photoresist 17 overlap parts of the end portions of the second pixel electrode 4G and the third pixel electrode 4B.

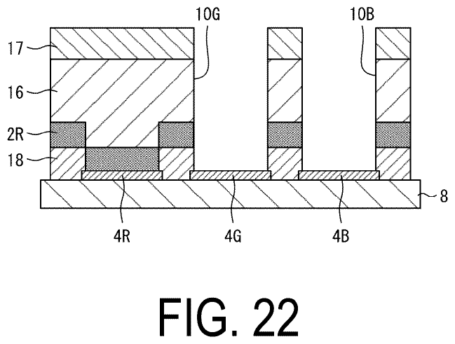

Next, as illustrated in FIG. 22, the first light-emitting layer 2R and the photoresist 18 present in the openings 10G and 10B of the protection layer 16 and the photoresist 17 are removed. By first removing the photoresist 18 below the first light-emitting layer 2R, the residue of the first light-emitting layer 2R is less likely to remain, and color mixing due to EL (Electro-Luminescence) light emission from the residue of the first light-emitting layer 2R can be suppressed.

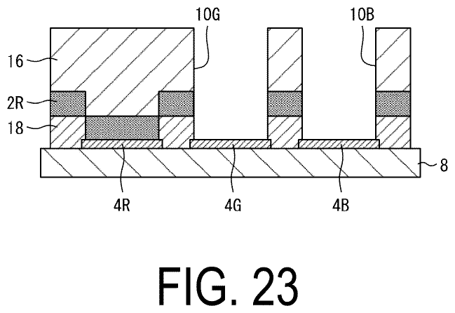

Then, as illustrated in FIG. 23, the photoresist 17 is removed. When the photoresist 17 damages the second light-emitting layer 2G and the third light-emitting layer 2B, by removing only the photoresist 17 in advance, it is possible to suppress contact between the second light-emitting layer 2G and the third light-emitting layer 2B and the photoresist 17 which is dissolved in the peeling solution in the step of peeling the protection layer 16. When the photoresist 17 does not damage the second light-emitting layer 2G and the third light-emitting layer 2B, the prior removal of the photoresist 17 is unnecessary.

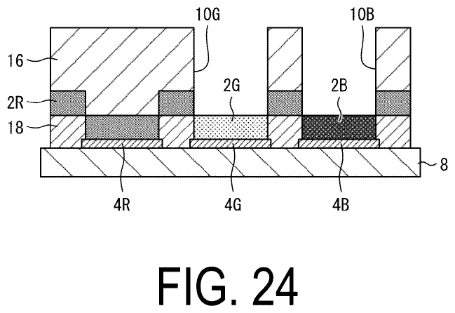

The ink dropped on the drop pattern portion 12G of the opening 10G spreads from the drop pattern portion 12G toward the capillary pattern portion 11G of the opening 10G by a capillary phenomenon, and the second light-emitting layer 2G is formed as illustrated in FIG. 24. The ink dropped on the drop pattern portion 12B of the opening 10B spreads from the drop pattern portion 12B toward the capillary pattern portion 11B of the opening 10B by a capillary phenomenon, and the third light-emitting layer 2B is formed as illustrated in FIG. 24.

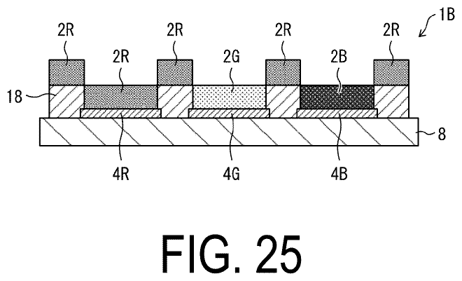

Next, as illustrated in FIG. 25, a plurality of light-emitting layers can be separately patterned by removing the protection layer 16, and further, if necessary, the charge transport layer and the common electrode are formed to cover the separately patterned light-emitting layers, thereby completing the display device 1B. Thus, three colors of the first light-emitting layer 2R, the second light-emitting layer 2G, and the third light-emitting layer 2B can be separately patterned by performing patterning twice. A desired light-emitting layer without mixed-color EL light emission can be formed in each pixel.

The photoresist 18 and the first light-emitting layer 2R are layered on the substrate 8 and function as an edge cover. Since the photoresist 18 and the first light-emitting layer 2R are layered, occurrence of leakage current between pixels is suppressed.

### Fourth Embodiment

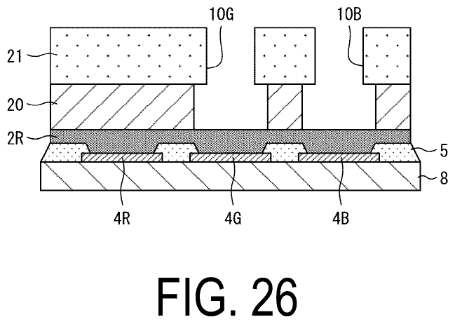

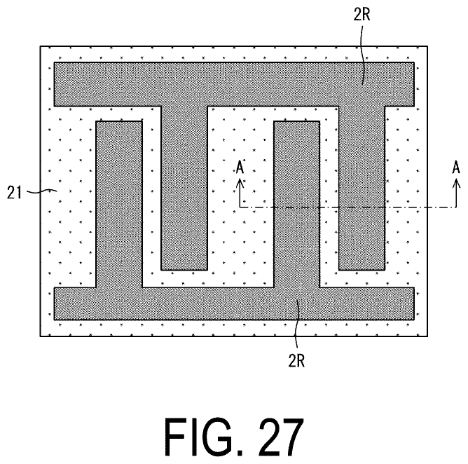

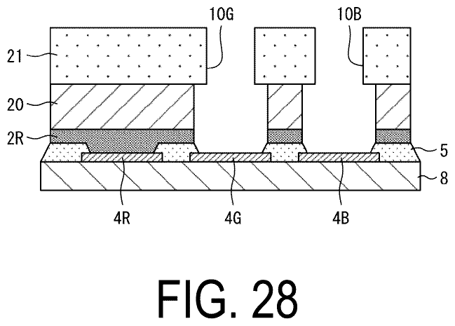

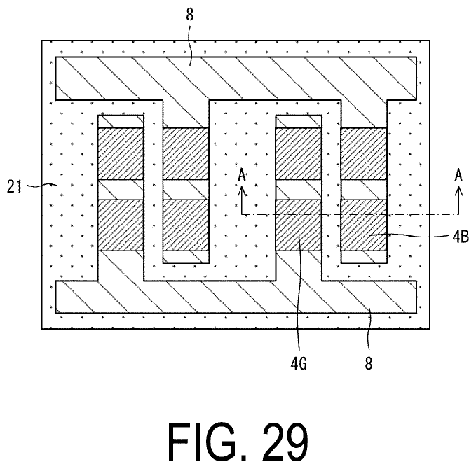

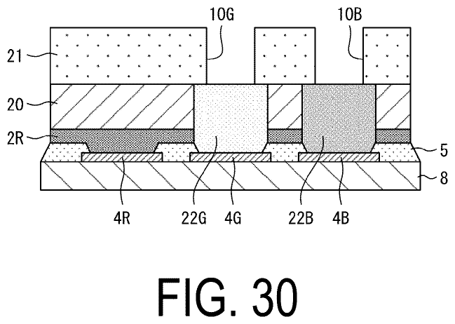

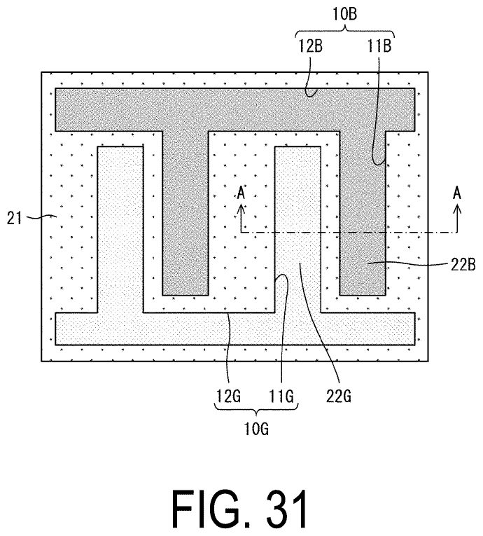

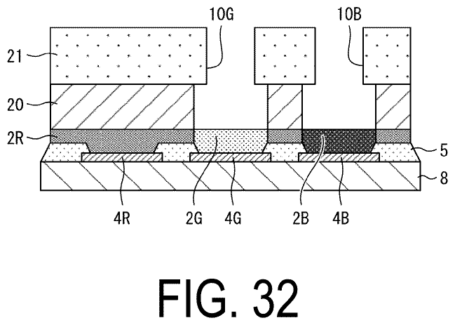

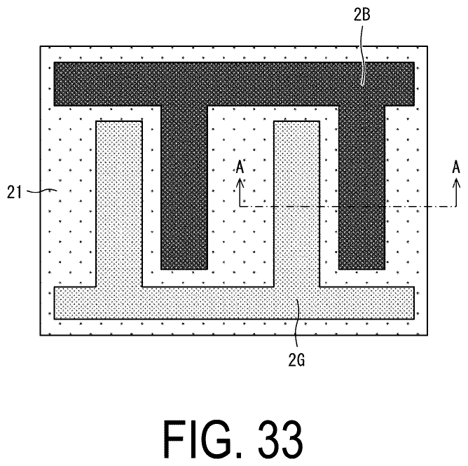

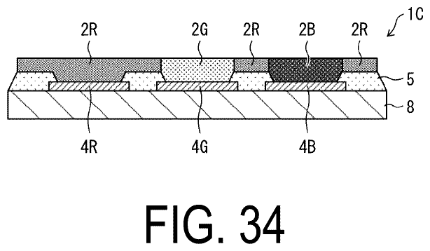

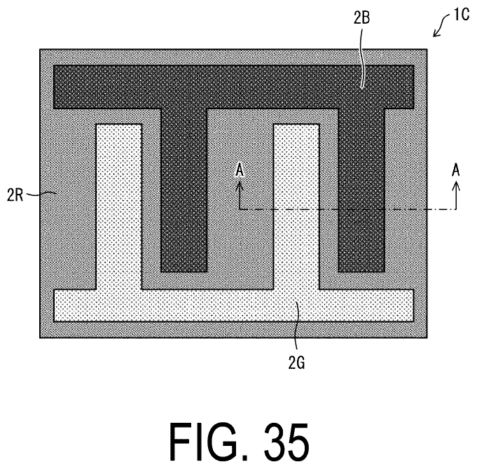

FIG. 26 is a cross-sectional view illustrating a manufacturing method for a display device 1C according to a fourth embodiment. FIG. 27 is a plan view corresponding to FIG. 26. FIG. 28 is another cross-sectional view illustrating the manufacturing method for the display device 1C. FIG. 29 is a plan view corresponding to FIG. 28. FIG. 30 is still another cross-sectional view illustrating the manufacturing method for the display device 1C. FIG. 31 is a plan view corresponding to FIG. 30. FIG. 32 is still another cross-sectional view illustrating the manufacturing method for the display device 1C. FIG. 33 is a plan view corresponding to FIG. 32. FIG. 34 is still another cross-sectional view illustrating the manufacturing method for the display device 1C. FIG. 35 is a plan view corresponding to FIG. 34. Constituent elements similar to/same as the constituent elements described above are given the same reference numerals. Thus, detailed descriptions of the constituent elements are not repeated.

FIG. 26 is a cross-sectional view taken along arrow A-A in FIG. 27. FIG. 28 is a cross-sectional view taken along arrow A-A in FIG. 29. FIG. 30 is a cross-sectional view taken along arrow A-A in FIG. 31. FIG. 32 is a cross-sectional view taken along arrow A-A in FIG. 33. FIG. 34 is a cross-sectional view taken along arrow A-A in FIG. 35.

Hereinafter, the manufacturing method for the display device 1C will be described.

First, as illustrated in FIGS. 26 and 27, the first pixel electrode 4R, the second pixel electrode 4G, and the third pixel electrode 4B are formed on the substrate 8. The edge cover 5 disposed between the first pixel electrode 4R, the second pixel electrode 4G, and the third pixel electrode 4B is formed on the substrate 8. The first light-emitting layer 2R is formed to cover the first pixel electrode 4R, the second pixel electrode 4G, the third pixel electrode 4B, and the edge cover 5. After that, a liquid non-repellent layer 20 is formed on the first light-emitting layer 2R, and a liquid repellent layer 21 is formed on the liquid non-repellent layer 20. The liquid non-repellent layer 20 and the liquid repellent layer 21 are collectively subjected to patterning to form the openings 10G and 10B.

Next, as illustrated in FIGS. 28 and 29, the first light-emitting layer 2R present in the openings 10G and 10B of the liquid non-repellent layer 20 and the liquid repellent layer 21 is removed by etching.

Thereafter, as illustrated in FIGS. 30 and 31, the solution drop material 22G in a liquid state dropped on the drop pattern portion 12G of the opening 10G spreads from the drop pattern portion 12G toward the capillary pattern portion 11G of the opening 10G by a capillary phenomenon. The solution drop material 22B in a liquid state dropped on the drop pattern portion 12B of the opening 10B spreads from the drop pattern portion 12B toward the capillary pattern portion 11B of the opening 10B by a capillary phenomenon. The solution drop materials 22G and 22B in a liquid state wet and spread along the liquid non-repellent layer 20, but do not wet and spread along the liquid repellent layer 21 because they are made liquid-repellent by the liquid repellent layer 21. Since the solution drop materials 22G and 22B in a liquid state do not wet and spread on the liquid repellent layer 21, the solution drop material 22G in a liquid state and the solution drop material 22B in a liquid state are prevented from getting over the liquid repellent layer 21 and being mixed with each other, thereby preventing color mixing of the display device.

As illustrated in FIGS. 32 and 33, the solution drop materials 22G and 22B in a liquid state are dried to form the second light-emitting layer 2G and the third light-emitting layer 2B.

Thereafter, as illustrated in FIGS. 34 and 35, the liquid non-repellent layer 20 and the liquid repellent layer 21 are peeled off to complete the display device 1C.

### Fifth Embodiment

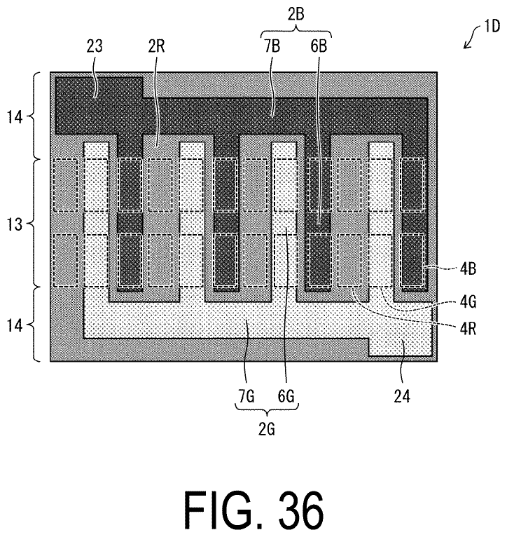

FIG. 36 is a plan view of a display device 1D according to a fifth embodiment. Constituent elements similar to/same as the constituent elements described above are given the same reference numerals. Thus, detailed descriptions of the constituent elements are not repeated.

The openings 10G and 10B of the mask pattern 9 for manufacturing the display device 1D further include a droplet drop pattern portion wider than the drop pattern portions 12G and 12B.

Thus, as illustrated in FIG. 36, the second light-emitting layer 2G of the display device 1D further includes a droplet drop region 24 wider than the connection region 7G. The third light-emitting layer 2B further includes a droplet drop region 23 wider than the connection region 7B.

As described above, the display device 1D includes the droplet drop region 24 wider than the connection region 7G so that the solution drop material 22G in a liquid state can be easily dropped, and the droplet drop region 23 wider than the connection region 7B so that the solution drop material 22B in a liquid state can be easily dropped.

### Sixth Embodiment

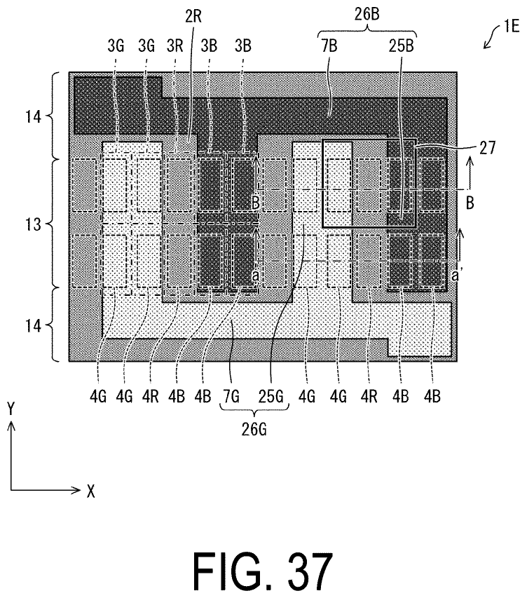

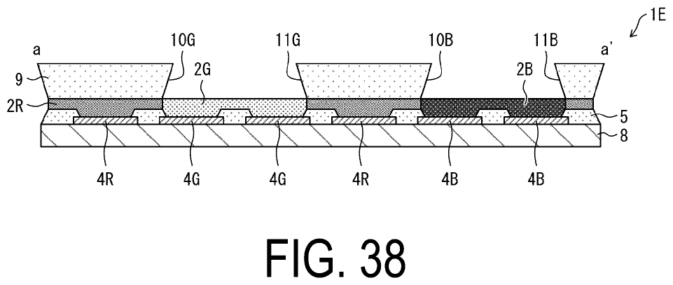

FIG. 37 is a plan view of a display device 1E according to a sixth embodiment. FIG. 38 is a cross-sectional view corresponding to FIG. 37. Constituent elements similar to/same as the constituent elements described above are given the same reference numerals. Thus, detailed descriptions of the constituent elements are not repeated.

FIG. 38 is a cross-sectional view taken along arrow B-B in FIG. 37.

The display device 1E includes a second light-emitting layer 26G and a third light-emitting layer 26B. The second light-emitting layer 26G includes a plurality of pixel regions 25G including the second pixels 3G disposed in two rows and two columns, and the connection region 7G connecting the plurality of pixel regions 25G. The third light-emitting layer 26B includes the plurality of pixel regions 25B including the third pixels 3B disposed in two rows and two columns, and the connection region 7B connecting the plurality of pixel regions 25B.

As described above, the second pixels 3G injected by using a capillary phenomenon are always arranged in two adjacent columns. The third pixels 3B injected by using a capillary phenomenon are always arranged in two adjacent columns.

The first pixel 3R is always interposed between the second pixel 3G and the third pixel 3B injected by a capillary phenomenon. Therefore, as illustrated in FIG. 38, the capillary pattern portion 11G of the opening 10G can be formed thick. The capillary pattern portion 11B of the opening 10B can be formed thick. Therefore, since the capillary pattern portions 11G and 11B of the mask pattern 9 do not need to be formed thin, the mask pattern 9 is less likely to come off, be peeled off, or be collapsed.

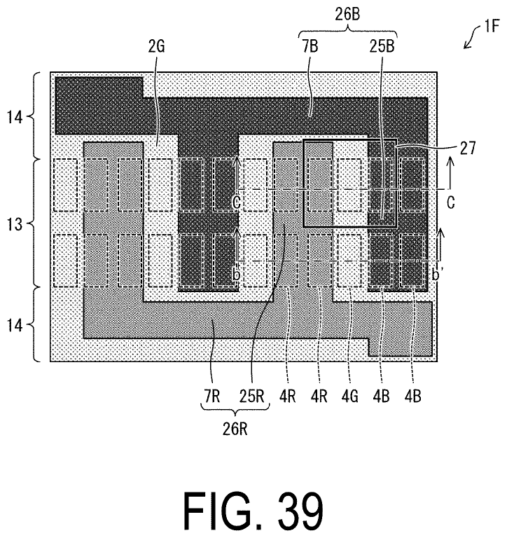

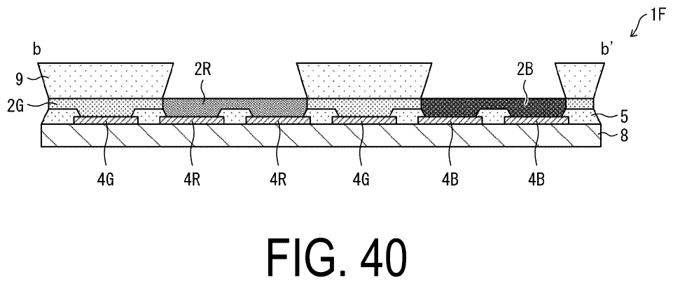

FIG. 39 is a plan view of a display device IF according to a modified example of the sixth embodiment. FIG. 40 is a cross-sectional view corresponding to FIG. 39. Constituent elements similar to/same as the constituent elements described above are given the same reference numerals. Thus, detailed descriptions of the constituent elements are not repeated.

FIG. 40 is a cross-sectional view taken along arrow C-C in FIG. 39.

In the display device 1F, the light-emitting layer of the first color to be formed first is the second light-emitting layer 2G, and the light-emitting layers to be injected using a capillary phenomenon are a first light-emitting layer 26R and a third light-emitting layer 26B. Accordingly, since the second light-emitting layers 2G of green having high brightness are disposed at regular intervals, the display quality in fine display is further improved.

### Seventh Embodiment

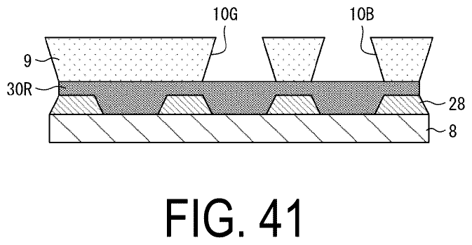

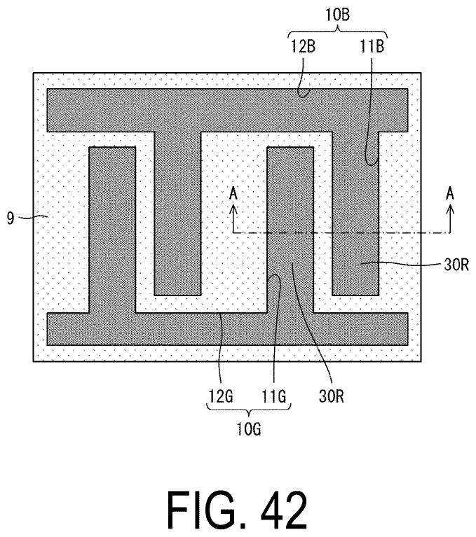

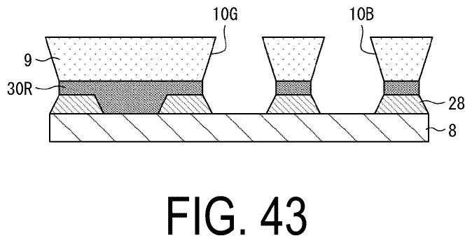

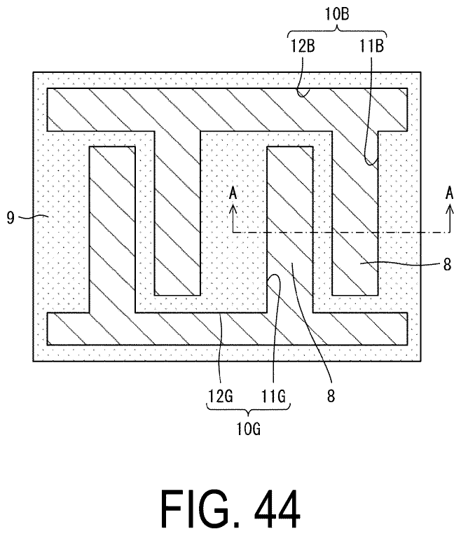

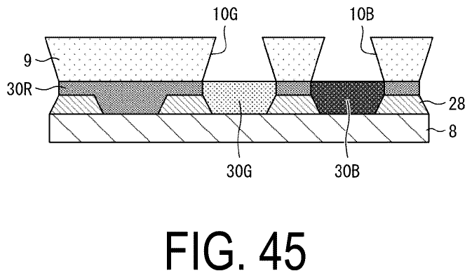

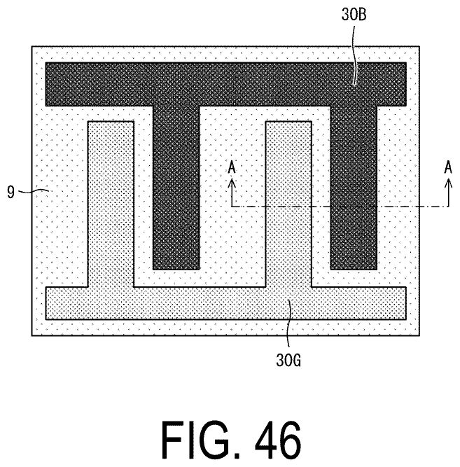

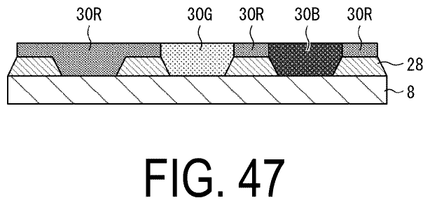

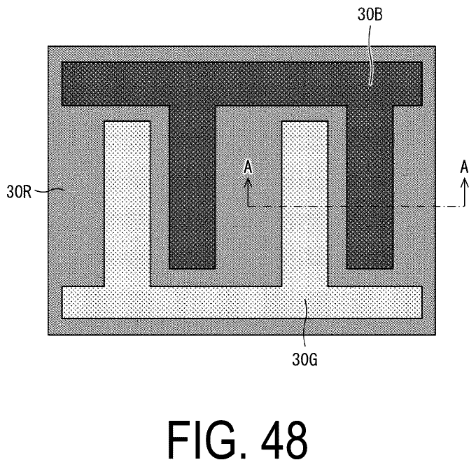

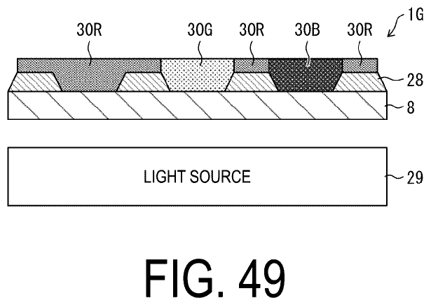

FIG. 41 is a cross-sectional view illustrating a manufacturing method for a display device 1G according to a seventh embodiment. FIG. 42 is a plan view corresponding to FIG. 41. FIG. 43 is another cross-sectional view illustrating the manufacturing method for the display device 1G. FIG. 44 is a plan view corresponding to FIG. 43. FIG. 45 is still another cross-sectional view illustrating the manufacturing method for the display device 1G. FIG. 46 is a plan view corresponding to FIG. 45. FIG. 47 is still another cross-sectional view illustrating the manufacturing method for the display device 1G. FIG. 48 is a plan view corresponding to FIG. 47. FIG. 49 is a cross-sectional view of the display device 1G. Constituent elements similar to/same as the constituent elements described above are given the same reference numerals. Thus, detailed descriptions of the constituent elements are not repeated.

FIG. 41 is a cross-sectional view taken along arrow A-A in FIG. 42. FIG. 43 is a cross-sectional view taken along arrow A-A in FIG. 44. FIG. 45 is a cross-sectional view taken along arrow A-A in FIG. 46. FIG. 47 is a cross-sectional view taken along arrow A-A in FIG. 48.

The display device 1G is manufactured by separately patterning a first color conversion layer 30R (first light layer), a second color conversion layer 30G (second light layer), and a third color conversion layer 30B instead of separately patterning the first light-emitting layer 2R, the second light-emitting layer 2G, and the third light-emitting layer 3B.

The display device 1G is basically manufactured by the same manufacturing method as that of the display devices 1, 1A to 1F including the first to third light-emitting layers 2R, 2G, and 2B. However, on the substrate 8 of the display device 1G, the first to third pixel electrodes 4R, 4G, and 4B and the edge cover 5 are not formed, but a light blocking layer 28 defining pixels is formed instead.

Hereinafter, the manufacturing method for the display device 1G will be described.

First, as illustrated in FIGS. 41 and 42, the light blocking layer 28 defining pixels is formed on the substrate 8. The planar first color conversion layer 30R (first light layer) including the first color conversion material associated with the first light having the first wavelength is formed to cover the light blocking layer 28 and the substrate 8. Next, the mask pattern 9 in which the openings 10G and 10B are formed is formed on the first color conversion layer 30R.

Thereafter, as illustrated in FIGS. 43 and 44, portions of the first color conversion layer 30R located below the openings 10G and 10B are removed from the first color conversion layer 30R.

As illustrated in FIGS. 45 and 46, the ink (second color conversion material) corresponding to the second color conversion layer 30G (second light layer) is fed from the drop pattern portion 12G of the opening 10G to the capillary pattern portion 11G by using a capillary phenomenon to form the second color conversion layer 30G. The ink corresponding to the third color conversion layer 30B (third light layer) is fed from the drop pattern portion 12B of the opening 10B to the capillary pattern portion 11B using a capillary phenomenon to form the third color conversion layer 30B.

Next, as illustrated in FIGS. 47 and 48, the mask pattern 9 is peeled from on the first color conversion layer 30R.

As illustrated in FIG. 49, a light source 29 may be disposed on the opposite side of the first to third color conversion layers 30R, 30G, and 30B with respect to the substrate 8, or may be disposed on the same side as the first to third color conversion layers 30R, 30G, and 30B. The light emitted from the light sources 29 and passing through the substrate 8 is converted into the first color light by the first color conversion layer 30R, and converted into the second color light by the second color conversion layer 30G. The edges of the first color conversion layer 30R, the second color conversion layer 30G, and the third color conversion layer 30B are in contact with each other, and light leakage of light from the light source 29 transmitted through the light blocking layer 28 is small. The light source 29 is capable of controlling light emission for each pixel, and an organic light emitting diode (OLED), a μ LED, a liquid crystal display (LCD), or the like can be used.

The first color conversion material is a material constituting the first color conversion layer 30R that converts the light from the light source 29 into the first light having the first wavelength. The second color conversion material is a material constituting the second color conversion layer 30G that converts the light from the light source 29 into the second light having the second wavelength.

The light source 29 includes third light having a wavelength shorter than the first wavelength and the second wavelength. The first color conversion material may be a material that absorbs the third light from the light source 29 and emits fluorescence of the first light. The second color conversion material may be a material that absorbs the third light from the light source 29 and emits fluorescence of the second light. The third color conversion material included in the third color conversion layer 30B is a material that emits light different from the first light and the second light. The third color conversion material may be a material that absorbs the third light from the light source 29 and emits fluorescence of light different from the first light and the second light. Alternatively, a material that transmits the third light from the light source 29 as it is or scatters and transmits the third light may be used. Alternatively, a material that absorbs and transmits or scatters and transmits a part of the third light from the light source 29 may be used.

If necessary, the first color conversion material, the second color conversion material, and the third color conversion material may be replaced with each other. For example, on the substrate on which the third color conversion layer 30B is subjected to patterning, the ink including the first color conversion material may be fed to the capillary pattern portion 11B by capillary phenomenon to form the first color conversion layer 30R, and the ink including the second color conversion material may be fed to the capillary pattern portion 11G by capillary phenomenon to form the second color conversion layer 30G.

As described above, the display device 1G includes the light source 29 for individually causing each pixel to optically excite and emit light.

The disclosure is not limited to the embodiments described above, and various modifications may be made within the scope of the claims. Embodiments obtained by appropriately combining technical approaches disclosed in the different embodiments also fall within the technical scope of the disclosure. For example, although the above-described embodiments include the first light layer, the second light layer, and the third light layer, the disclosure is not limited to this configuration, and a configuration including only the first light layer and the second light layer may be employed. Furthermore, novel technical features can be formed by combining the technical approaches disclosed in each of the embodiments.

1. A display device manufacturing method comprising:
forming a first light layer in a planar shape including a first light material associated with first light having a first wavelength;
forming a mask pattern on the first light layer, the mask pattern including an opening formed over a plurality of sub-pixel formation regions;
removing a portion of the first light layer located below the opening;
feeding an ink to below at least a portion of the opening, the ink including a second light material associated with second light having a second wavelength to form a second light layer including the second light material; and
removing the mask pattern.

2. The display device manufacturing method according to claim 1,
wherein the first light material includes a first light-emitting material,
the first light layer includes a first light-emitting layer,
the second light material includes a second light-emitting material, and
the second light layer includes a second light-emitting layer.

3. The display device manufacturing method according to claim 1,
wherein the first light material includes a first color conversion material,
the first light layer includes a first color conversion layer,
the second light material includes a second color conversion material, and
the second light layer includes a second color conversion layer.

4. The display device manufacturing method according to claim 1,
wherein the ink is fed using a capillary phenomenon in the opening.

5. The display device manufacturing method according to claim 2,
wherein an ink including the second light-emitting material is fed to below the portion of the opening and an ink including a third light-emitting material is fed to below a remaining portion of the opening, to form a third light-emitting layer including the third light-emitting material.

6. The display device manufacturing method according to claim 2, further comprising:
forming a first pixel electrode corresponding to the first light-emitting material and a second pixel electrode corresponding to the second light-emitting material on a substrate before forming the first light layer; and
forming an edge cover on the substrate, the edge cover being disposed between the first pixel electrode and the second pixel electrode,
wherein the mask pattern overlaps the edge cover in a plan view.

7. The display device manufacturing method according to claim 2,
wherein the display device includes a plurality of pixels, and
the second light-emitting layer corresponding to the second light-emitting material is formed through a plurality of pixels.

8. The display device manufacturing method according to claim 1,
wherein the mask pattern includes
a plurality of capillary pattern portions associated with a capillary phenomenon of the ink and
a connection pattern portion configured to connect a plurality of the capillary pattern portions.

9. The display device manufacturing method according to claim 1,
wherein the mask pattern includes
the plurality of capillary pattern portions associated with a capillary phenomenon of the ink and
a connection pattern portion thicker than the capillary pattern portions.

10. The display device manufacturing method according to claim 1,
wherein the mask pattern includes
a plurality of capillary pattern portions associated with a capillary phenomenon of the ink and
a connection pattern portion configured to connect the plurality of capillary pattern portions, and
the ink is dropped on the connection pattern portion.

11. The display device manufacturing method according to claim 2,
wherein the second light-emitting layer is formed in a manner that an end face of the first light-emitting layer corresponding to the first light-emitting material is in contact with an end face of the second light-emitting layer corresponding to the second light-emitting material.

12. The display device manufacturing method according to claim 2,
wherein forming the first light layer includes
forming a first light-emitting layer mask pattern including a first light-emitting layer formation opening configured to form the first light-emitting layer on a substrate, and
forming the first light-emitting layer by applying the first light-emitting material in such a manner as to cover the first light-emitting layer mask pattern and the first light-emitting layer formation opening.

13. The display device manufacturing method according to claim 2,
wherein the mask pattern includes a liquid non-repellent layer formed on a side of the first light-emitting layer, and a liquid repellent layer formed on the liquid non-repellent layer.

14. The display device manufacturing method according to claim 8,
wherein the opening further includes a droplet drop pattern portion having a width larger than a width of the connection pattern portion.

15. A display device comprising:
a first light layer continuously formed over a plurality of first pixels in association with first light having a first wavelength; and
a second light layer continuously formed over a plurality of second pixels in association with second light having a second wavelength, the second light layer not overlapping the first light layer in a plan view,
wherein the second light layer includes a solid dispersed or dissolved in a solution drop material in a liquid state, and
the first light layer is formed overlapping a part of an outer peripheral portion of each of the pixels in a plan view.

16. The display device according to claim 15,
wherein the first light layer includes a first light-emitting layer, and
the second light layer includes a second light-emitting layer.

17. (canceled)

18. The display device according to claim 16,
wherein each of the plurality of first pixels includes a first pixel electrode corresponding to the first light-emitting layer,
each of the plurality of second pixels includes a second pixel electrode corresponding to the second light-emitting layer,
the display device further comprises an edge cover covering edges of the first pixel electrode and the second pixel electrode, and
the first light-emitting layer is formed overlapping a part of the edge cover in a plan view.

19. The display device according to claim 16,
wherein the second light-emitting layer is formed in a manner that an end face of the first light-emitting layer is in contact with an end face of the second light-emitting layer.

20-22. (canceled)

23. The display device according to claim 16, further comprising:
a third light-emitting layer continuously formed over a plurality of third pixels and not overlapping the first light-emitting layer and the second light-emitting layer in a plan view,
each of the plurality of first pixels is disposed between the second pixel and the third pixel,
the first light-emitting layer emits green light, and
the second light-emitting layer emits one of red light and blue light.

24-28. (canceled)

29. The display device according to claim 15, further comprising:
a light source configured to individually cause each of the pixels to emit light by optical excitation.
